(19) United States
(12) Patent Application Publication
(10) Pub. No.: US 2025/0105822 A1
(43) Pub. Date: Mar. 27, 2025

(54) FILTER DEVICE, SPLITTER, AND COMMUNICATION DEVICE

(71) Applicant: KYOCERA CORPORATON, Kyoto-shi, Kyoto (JP)

(72) Inventor: Naofumi KASAMATSU, Nara-shi (JP)

(73) Assignee: KYOCERA CORPORATON, Kyoto-shi, Kyoto (JP)

(21) Appl. No.: 18/726,867

(22) PCT Filed: Jan. 6, 2023
(86) PCT No.: PCT/JP2023/000139

§ 371 Date: Jul. 5, 2024

(30) Foreign Application Priority Data
Jul. 1, 2022 (JP) 2022-001787

(51) Int. Cl. H03H 9/54; H03H 7/01; H03H 9/13; H04B 1/00

(52) U.S. Cl. CPC H03H 9/542; H03H 7/0115; H03H 9/13; H04B 1/0057

(57) ABSTRACT

In a filter device including at least one acoustic wave resonator, the acoustic wave resonator includes a piezoelectric film having a piezoelectric property and an interdigital transducer electrode that is positioned on an upper surface of the piezoelectric film and that includes a plurality of electrode fingers. When a value double a pitch of the plurality of electrode fingers is defined as λ and a duty of the plurality of electrode fingers is defined as d, a thickness T of the piezoelectric film satisfies formula (1) below. The filter device has a second attenuation pole by using sub-resonance of the acoustic wave resonator on a high-frequency side of a passband of the filter device. 0.154λ_{d}≤T≤0.264λ_{d}(1), where λ_{d} satisfies formula (2) below: λ_{d}=λ/(−0.6111×d²−0.1792×d+1.2449) (2).

### TECHNICAL FIELD

The present disclosure relates to a filter device that utilizes an acoustic wave. The present disclosure also relates to a splitter and a communication device that include the filter device.

### BACKGROUND OF INVENTION

In recent communication services, communication bands have been widened and a plurality of bands have been simultaneously used in response to an increase in capacity of communication and an increase in communication speed.

A ladder-type surface acoustic wave filter including an inductor is disclosed in Patent Literature 1. In the ladder-type surface acoustic wave filter disclosed in Patent Literature 1, a passband is widened and an attenuation pole is formed in a stopband on a high frequency side relative to the passband.

### CITATION LIST

### Patent Literature

Patent Literature 1: Japanese Patent No. 5907254

### SUMMARY

A filter device according to an embodiment of the present disclosure includes at least one acoustic wave resonator. The acoustic wave resonator includes a piezoelectric film having a piezoelectric property and an interdigital transducer electrode that is positioned on an upper surface of the piezoelectric film and that includes a plurality of electrode fingers. When a value double a pitch of the plurality of electrode fingers is defined as λ and a duty of the plurality of electrode fingers is defined as d, a thickness T of the piezoelectric film satisfies formula (1) below. The filter device has a second attenuation pole by using sub-resonance of the acoustic wave resonator on a high-frequency side of a passband of the filter device.

$$0 \text{.154} {λ}_{d} \leq T \leq 0 \text{.264} {λ}_{d} , \qquad ( 1 )$$

where λ_{d} satisfies formula (2) below:

$${λ}_{d} = λ / ( - 0.6111 \times {d}^{2} - 0.1792 \times d + 1.2449 ) . \qquad ( 2 )$$

A splitter according to an embodiment of the present disclosure includes an antenna terminal, a transmission filter configured to filter a signal to be output to the antenna terminal, and a reception filter configured to filter a signal to be input from the antenna terminal. At least one of the transmission filter or the reception filter includes the above-described filter device.

A communication device according to an embodiment of the present disclosure includes an antenna, the above-described splitter in which the antenna terminal is connected to the antenna, and an integrated circuit connected to the transmission filter and the reception filter.

### BRIEF DESCRIPTION OF THE DRAWINGS

FIG. 1 is a schematic block diagram of a filter device according to an embodiment of the present disclosure.

FIG. 2 is a schematic view illustrating a state in which an LC filter is formed in a multilayer substrate in the filter device according to an embodiment of the present disclosure.

FIG. 3 is a schematic sectional diagram of an acoustic wave resonator according to an embodiment of the present disclosure.

FIGS. 4A and 4B are schematic sectional views of the acoustic wave resonator according to an embodiment of the present disclosure.

FIG. 5 is a plan view of the acoustic wave resonator according to an embodiment of the present disclosure.

FIG. 6 illustrates frequency characteristics of an acoustic wave filter according to an embodiment of the present disclosure.

FIG. 7 illustrates the frequency characteristics of the acoustic wave filter when a thickness T of the piezoelectric film is varied under the conditions of FIG. 6.

FIG. 8 illustrates the frequency characteristics of the acoustic wave filter when the thickness T of the piezoelectric film is varied under the conditions of FIG. 6.

FIG. 9 illustrates a corrected pitch p_{d} of electrode fingers when an anti-resonant frequency and a duty d of the electrode fingers of the acoustic wave resonator according to an embodiment of the present disclosure are varied.

FIGS. 10A, 10B, 10C, 10D, 10E, and 10F illustrate simulation results of the frequency characteristics of the acoustic wave filter when the anti-resonant frequency and the duty d of the electrode fingers according to an embodiment of the present disclosure are varied.

FIG. 11 is a schematic block diagram of a filter device according to another example of the present disclosure.

FIG. 12 schematically illustrates a splitter as an example of utilization of the filter device according to an embodiment of the present disclosure.

FIG. 13 is a block diagram illustrating a configuration of a main part of a communication device as an example of utilization of the splitter illustrated in FIG. 12.

### DESCRIPTION OF EMBODIMENTS

Hereinafter, an embodiment according to the present disclosure is described with reference to the drawings. The drawings to be used in the description below are merely schematic, and ratios of dimensions or the like in the drawings do not necessarily agree with the actual ratios of dimensions or the like.

For convenience, a rectangular coordinate system consisting of an X axis, a Y axis, and a Z axis may be provided in the drawings. Regarding a filter device according to the present disclosure, any direction may be defined as an upper direction or a lower direction. However, for convenience, the term “upper surface” or “lower surface” may be used with the Z axis direction defined as the upper-lower direction. The X axis is defined so as to be perpendicular to a propagation direction of a surface acoustic wave (SAW) propagating along an upper surface of a piezoelectric film 4, which will be described later. The Y axis is defined so as to be parallel to the upper surface of the piezoelectric film 4 and perpendicular to the X axis. The Z axis is defined so as to be perpendicular to the upper surface of the piezoelectric film 4.

The embodiment to be described herein is merely exemplary. Thus, different portions of the embodiment may be partially replaced with each other and different examples may be partially replaced with each other. In addition, different portions of the embodiment may be partially combined with each other, and different examples may be partially combined with each other.

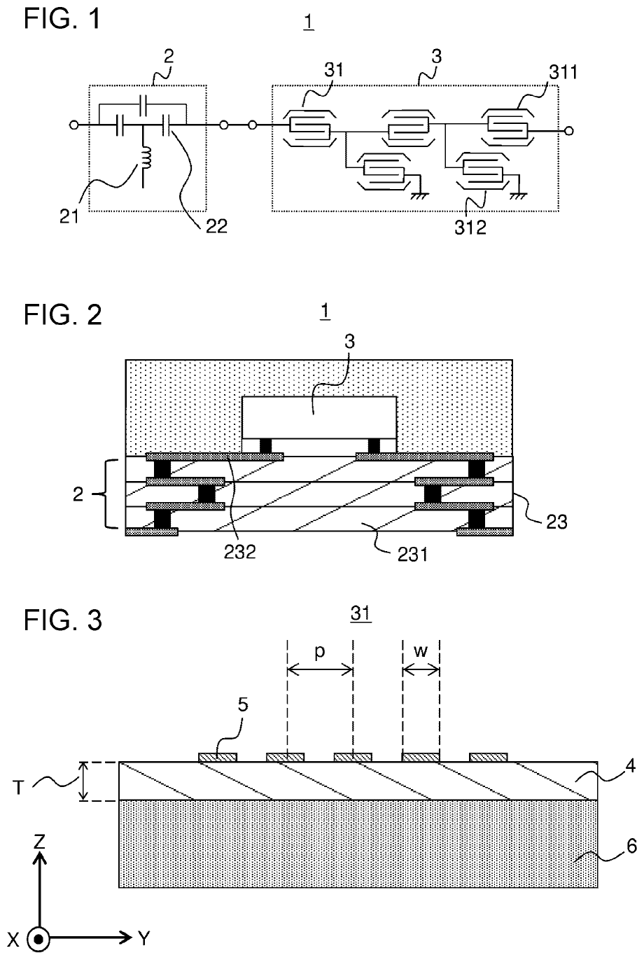

FIG. 1 is a schematic block diagram of a filter device 1 according to an embodiment of the present disclosure. As illustrated in FIG. 1, the filter device 1 includes an LC filter 2 and an acoustic wave filter 3 including at least one acoustic wave resonator 31. The LC filter 2 includes, for example, at least one inductor 21 and at least one capacitor 22. A configuration of the LC filter 2 is not limited to the example illustrated in FIG. 1. Arrangement and the numbers of the at least one inductor 21 and the at least one capacitor 22 may be appropriately set.

The LC filter 2 is a filter in which a passband of the filter is formed by LC resonance and may be, for example, one selected from the group consisting of a band-pass filter (BPF), a high-pass filter (HPF), and a low-pass filter (LPF).

As illustrated in FIG. 2, as an example, the LC filter 2 may be formed as a multilayer substrate 23 formed by laminating a plurality of dielectric layers 231 and a plurality of conductor layers 232. Examples of the dielectric layers 231 can include, for example, ceramic and resin. As an example, according to an embodiment of the present disclosure, the multilayer substrate 23 may be a low temperature co-fired ceramics (LTCC) substrate in which the dielectric layers 231 include ceramic. The form of the multilayer substrate 23 is not limited to this example. For example, the multilayer substrate 23 may be a glass epoxy substrate in which the dielectric layers 231 include a glass fabric and epoxy resin.

When the at least one capacitor 22 includes a plurality of capacitors 22, at least a subset of the plurality of capacitors 22 of the LC filter 2 may be formed on the piezoelectric film 4 of the acoustic wave resonator 31, which will be described later. With such a configuration, the size of the LC filter 2 can be reduced.

According to an embodiment of the present disclosure, the acoustic wave filter 3 includes at least one resonator. The resonator included in the acoustic wave filter 3 may be a surface acoustic wave (SAW) resonator or a bulk acoustic wave (BAW) resonator. The acoustic wave filter 3 may be composed of a single resonator or a plurality of resonators.

Specifically, according to an embodiment of the present disclosure, the acoustic wave filter 3 is a ladder filter including at least one series resonator 311 and at least one parallel resonator 312. A configuration of the acoustic wave filter 3 is not limited to a configuration of a ladder filter. The acoustic wave filter 3 may be configurated in any manner. For example, the acoustic wave filter 3 may be a longitudinally coupled acoustic wave filter or a filter composed of a single resonator.

The acoustic wave filter 3 may be a band elimination filter (BEF) or one selected from the group consisting of a BPF, an HPF, and an LPF. Specifically, the acoustic wave filter 3 according to an embodiment of the present disclosure is a BEF.

According to an embodiment of the present disclosure, at least one resonator out of the resonators included in the acoustic wave filter 3 is the acoustic wave resonator 31, which will be described later. The acoustic wave resonator 31 may be a parallel resonator or a series resonator. The number of at least one acoustic wave resonator 31 can be arbitrarily set. For example, the acoustic wave filter 3 may include a single acoustic wave resonator 31 or a plurality of acoustic wave resonators 31. All the resonators included in the acoustic wave filter 3 may be acoustic wave resonators 31. Specifically, according to an embodiment of the present disclosure, all the resonators of the acoustic wave filter 3 are the acoustic wave resonators 31.

As illustrated in FIG. 3, each of the acoustic wave resonators 31 includes the piezoelectric film 4, an interdigital transducer (IDT) electrode 5, and a supporting substrate 6. The piezoelectric film 4 is positioned on an upper surface of the supporting substrate 6.

Although it is not particularly limited, a thickness of the supporting substrate 6 is, for example, greater than a thickness of the piezoelectric film 4, which will be described later.

A material of the supporting substrate 6 is not particularly limited as long as the material has a certain strength. For example, when the supporting substrate 6 includes a material having a smaller linear expansion coefficient than that of the piezoelectric film 4, characteristic variation due to temperature variation can be reduced by reducing deformation of the piezoelectric film 4 due to temperature variation. The material of the supporting substrate 6 may allow an acoustic wave to propagate therethrough at a higher acoustic velocity of the transverse wave than an acoustic velocity of the transverse wave of an acoustic wave propagating through the piezoelectric film 4. When the selected material of the supporting substrate 6 allows the acoustic wave to propagate therethrough at the higher acoustic velocity of the transverse wave than the acoustic velocity of the transverse wave of the acoustic wave propagating through the piezoelectric film 4, the acoustic wave can be confined in the piezoelectric film 4, and the acoustic wave resonator 31 having good frequency characteristics can be provided. Although it is not particularly limited, the thickness of the supporting substrate 6 is, for example, greater than the thickness of the piezoelectric film 4, which will be described later.

For example, examples of the materials of the supporting substrate 6 can include, for example, sapphire (Al₂O₃) and silicon (Si). In the example described according to an embodiment of the present disclosure, Si is used for the supporting substrate 6.

When the Z axis is assumed as the upper-lower direction, the piezoelectric film 4 includes an upper surface and a lower surface perpendicular to the Z axis. The above-described supporting substrate 6 is positioned on the lower surface side of the piezoelectric film 4, and the IDT electrode 5 to be described later is positioned on the upper surface of the piezoelectric film 4.

The lower surface of the piezoelectric film 4 and the supporting substrate 6 may be in direct contact with each other or in indirect contact with each other with, for example, an intermediate layer, a bonding layer, or the like (not illustrated) interposed therebetween.

Examples of such an intermediate layer include insulative materials such as silicon dioxide (SiO₂), silicon nitride (Si₃N₄), and aluminum oxide (Al₂O₃). When such an insulative intermediate layer is provided, the occurrences of situations such as formation of an unnecessary potential and formation of unnecessary capacity can be reduced. Thus, electrical characteristics of the acoustic wave filter 3 can be improved.

Both the bonding layer and the intermediate layer may be positioned between the piezoelectric film 4 and the supporting substrate 6. For example, when both the bonding layer and the intermediate layer are positioned between the piezoelectric film 4 and the supporting substrate 6, the bonding layer is positioned between the supporting substrate 6 and the intermediate layer. Examples of such a bonding layer include amorphous silicon.

For example, an alumina film or the like (not illustrated) may be further positioned between the intermediate layer and the piezoelectric film 4. Existence of such an alumina film can reduce leakage of the acoustic wave in the piezoelectric film 4 to the supporting substrate 6 side. Thus, the frequency characteristics of the acoustic wave resonator 31 can be improved.

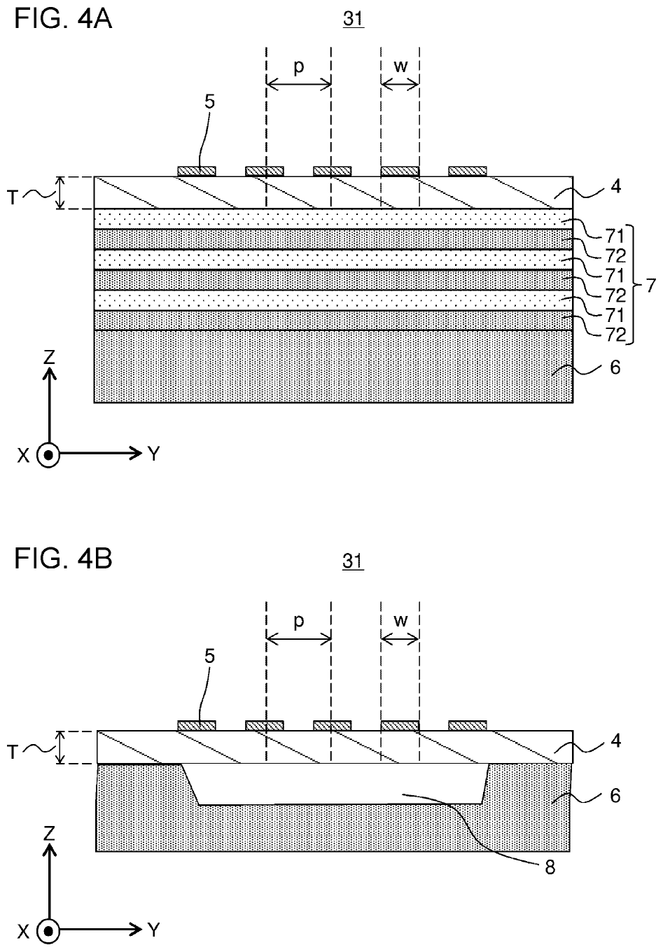

FIGS. 4A and 4B illustrate schematic sectional views of the acoustic wave resonator 31 according to an embodiment of the present disclosure. As illustrated in FIG. 4A, according to an embodiment of the present disclosure, a multilayer film layer 7 may be positioned between the piezoelectric film 4 and the supporting substrate 6. In the multilayer film layer 7, low acoustic impedance layers 71 and high acoustic impedance layers 72 are alternately laminated. The acoustic impedance of the low acoustic impedance layers 71 is lower than the acoustic impedance of the piezoelectric film 4, and the acoustic impedance of the high acoustic impedance layers 72 is higher than the acoustic impedance of the low acoustic impedance layers 71.

As illustrated in FIG. 4B, according to an embodiment of the present disclosure, the supporting substrate 6 may include a cavity 8 in the upper surface thereof. At this time, the piezoelectric film 4 covers the cavity 8 of the supporting substrate 6 in plan view such that an inner space of the cavity 8 is empty.

The size and the depth of the cavity 8 may be appropriately set.

The intermediate layer or the like (not illustrated) may be positioned on the upper surface side of the supporting substrate 6 including the cavity 8. At this time, the intermediate layer and the piezoelectric film 4 covers the cavity 8 of the supporting substrate 6 in plan view such that the inner space of the cavity 8 is empty.

The multilayer film layer 7 may be positioned on the upper surface side of the supporting substrate 6 including the cavity 8. At this time, the multilayer film layer 7 and the piezoelectric film 4 covers the cavity 8 of the supporting substrate 6 in plan view such that the inner space of the cavity 8 is empty.

A substrate or the like (not illustrated) may be provided on a lower surface side of the supporting substrate 6 including the cavity 8.

For example, the piezoelectric film 4 may include a piezoelectric monocrystalline substrate including a lithium tantalate (LiTaO₃, hereinafter, referred to as LT) crystal, a piezoelectric monocrystalline substrate including a lithium niobate (LiNbO₃, hereinafter, referred to as LN) crystal, or the like. Specifically, according to the embodiment of the present disclosure, the piezoelectric film 4 includes LN.

The thickness of the piezoelectric film 4 is defined as T.

The IDT electrode 5 is positioned on the upper surface of the piezoelectric film 4. The IDT electrode 5 includes an electrically conductive material. Examples of the material of the IDT electrode 5 can include various electrically conductive materials such as, for example, Al, Cu, Pt, Mo, Au, and an alloy of these. Furthermore, in the IDT electrode 5, a plurality of layers of these may be laminated. When the IDT electrode 5 includes a laminated body including the plurality of layers, a ground layer (not illustrated) may be disposed in the interface between the laminated layers.

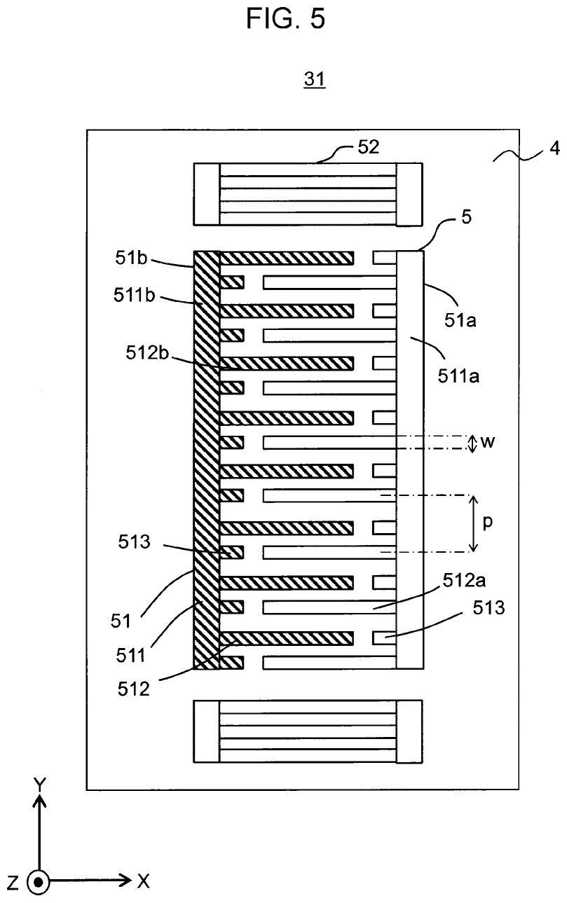

FIG. 5 illustrates the shape of the IDT electrode 5. The IDT electrode 5 is included in a resonator that includes, for example, a pair of comb-shaped electrodes 51a and 51b. Hereinafter, the comb-shaped electrodes 51a and 51b may be collectively referred to as comb-shaped electrodes 51.

The comb-shaped electrodes 51 include two busbars 511 and a plurality of elongated electrode fingers 512. The electrode fingers 512 are each connected to one of the busbars 511. Electrode fingers 512a connected to one busbar 511a and electrode fingers 512b connected to the other busbar 511b are alternately arranged. A plurality of dummy electrodes 513 are provided such that the dummy electrodes 513 each face a distal end of a corresponding one of the electrode fingers 512 connected to one of the busbars 511 while being connected to the other of the busbars 511.

The lengths of the plurality of electrode fingers 512 are, for example, equal to each other. A so-called apodization may be applied to the IDT electrode 5 so that the lengths of the plurality of electrode fingers 512 (intersecting widths in a different viewpoint) are different depending on the positions in the propagation direction. The length and thickness of the electrode fingers 512 may be appropriately set in accordance with required electrical characteristics or the like.

A repetition distance of the electrode fingers 512a and 512b is defined as a pitch p, and the width of the electrode fingers 512 is defined as w. A duty d of the IDT electrode 5 represents the ratio of an electrode finger width to the pitch p. That is, the duty d of the IDT electrode 5 can be represented as w/p. The pitch p and an electrode finger width w may indicate, for example, respective average values of the pitches and the electrode finger widths in each of the acoustic wave resonators 31 or values of these at a specific acoustic wave resonator 31.

Application of a radio-frequency signal to such an IDT electrode 5 excites an SAW of a wavelength λ defined as a value double the pitch p of the electrode fingers 512. A resonant frequency fr of the acoustic wave resonator 31 is substantially equivalent to the frequency of the excited SAW. An anti-resonant frequency fa is determined by the resonant frequency fr and a capacity ratio. The capacity ratio is mainly defined by a configuration of the piezoelectric film 4 and can be varied by the duty d. The capacity ratio can be finely adjusted with the number, an intersecting width, a film thickness, and the like of the electrode fingers 512.

A pair of reflectors 52 may be positioned on both sides of the IDT electrode 5 in the propagation direction of the SAW. The pair of reflectors 52 each include a pair of reflector busbars facing each other and a plurality of strip electrodes extending between the pair of reflector busbars.

The acoustic wave filter 3 forms a main resonance in a specific frequency band. The main resonance is formed by a resonance at the resonant frequency fr or the anti-resonant frequency fa of the resonators included in the acoustic wave filter 3. For example, when the acoustic wave filter 3 is a BEF, the main resonance is formed by the resonance at the anti-resonant frequency fa of the series resonator 311 included in the acoustic wave filter 3. This main resonance is utilized for formation of an attenuation pole.

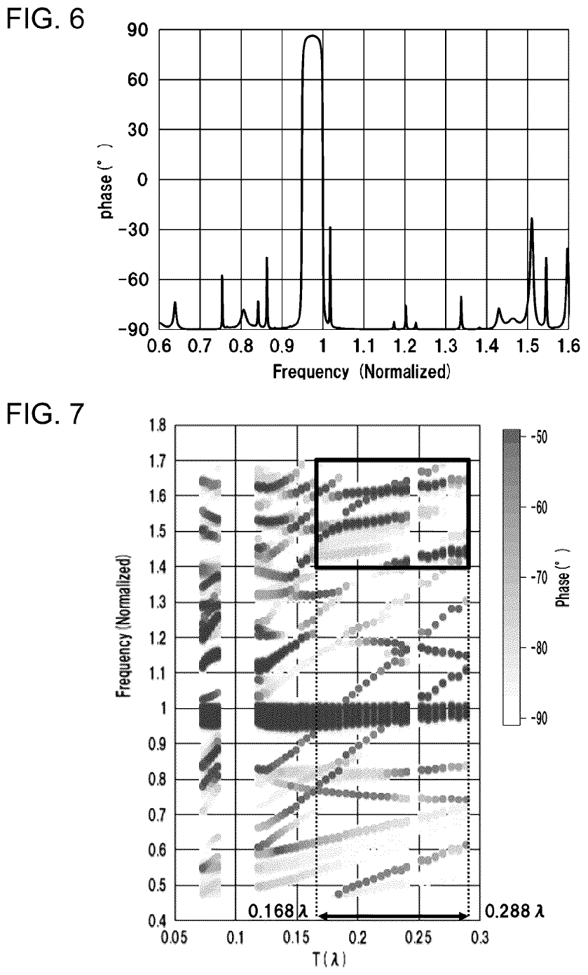

FIG. 6 represents, as an example, frequency characteristics of the acoustic wave filter 3 when the LN is the material included in the piezoelectric film 4 and the duty d of the IDT electrode 5 is set to 0.6. In FIG. 6, a vertical axis represents the phase, and a horizontal axis represents the normalized frequency. The normalized frequency refers to a value obtained by dividing the value of the frequency by the anti-resonant frequency fa of the acoustic wave resonator 31 and normalizing the result of division. That is, the anti-resonant frequency fa of the acoustic wave resonator 31 is 1 when represented as the normalized frequency.

Conditions listed below are conditions other than the above-described conditions in a simulation calculation with which the frequency characteristics illustrated in FIG. 6 are obtained.
Euler angle of piezoelectric film (ϕ, θ, ψ)=(0°, 15°, 0°)
Material of electrode: laminated structure of Ti layer and Al—Cu alloy layer on Ti layer. Cu is 1 wt %.
Thickness of electrode: Ti=6 nm, Al—Cu alloy=118 nm (124 nm in total)
Structure of substrate: structure of FIG. 4A
Thickness of piezoelectric body (T): 470 nm
Material of multilayer film:
   low acoustic impedance layer: SiO₂
   high acoustic impedance layer: HfO₂
Material of supporting substrate: Si
Pitch of electrode fingers: 1.22 μm

For example, when the acoustic wave filter 3 is the BEF, setting a passband of the LC filter 2 on the high-frequency side relative to the main resonance of the acoustic wave filter 3 improves attenuation characteristics of the LC filter 2 outside the passband. Thus, the steepness can be improved. Accordingly, the main resonance of the acoustic wave filter 3 can be utilized for the formation of the attenuation pole. This attenuation pole by using the main resonance of the acoustic wave filter 3 is defined as a first attenuation pole.

As is clearly seen from FIG. 6, with the acoustic wave resonator 31, spurious is generated on the high-frequency side of the anti-resonant frequency fa. The spurious includes the resonance due to an acoustic wave mode different from that of the main resonance. In particular, it has been found that, in a region where the normalized frequency is higher than or equal to about 1.4, comparatively large sub-resonance (spurious) is generated.

The position where the above-described sub-resonance is generated changes as the thickness T of the piezoelectric film 4 varies. FIG. 7 illustrates a simulation result of the frequency characteristics of the acoustic wave filter 3 when the thickness T of the piezoelectric film 4 is varied under the conditions set in FIG. 6. In FIG. 7, the resonance is represented by dots, and light and shade of the color represents the size of the phase of the resonance. Also in FIG. 7, the vertical axis represents the normalized frequency, and the horizontal axis represents the thickness T of the piezoelectric film 4. The thickness T of the piezoelectric film 4 is represented by using the wavelength λ defined as a value double the pitch p of the electrode fingers 512.

As is clearly seen from FIG. 7, when the thickness T of the piezoelectric film 4 is in a range from 0.05λ to 0.15λ, comparatively large spurious is generated in a region where the normalized frequency is about 1 to 1.4. Meanwhile, it has been found that, when the thickness T of the piezoelectric film 4 is in a range from 0.168λ to 0.288λ, comparatively large sub-resonance is generated in a region which is separated from the main resonance and in which the normalized frequency is higher than or equal to about 1.4. That is, when the frequency of the sub-resonance of the acoustic wave resonator 31 is fb, the normalized frequency of the sub-resonance (fb/fa) is higher than or equal to 1.4 in a range of the thickness T of the piezoelectric film 4 from 0.168λ to 0.288λ.

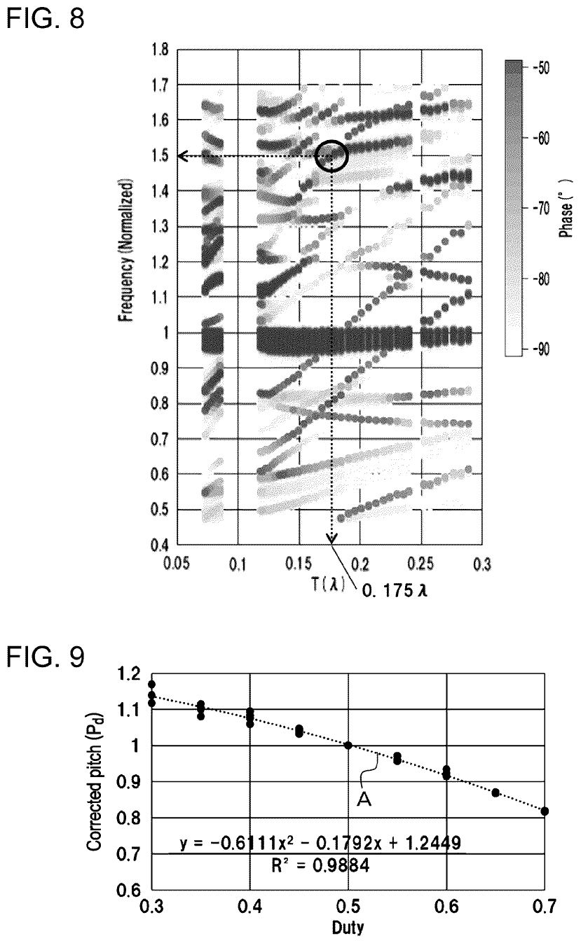

From the result of FIG. 7, it has been found that the frequency generated by the sub-resonance can be adjusted by adjusting the thickness T of the piezoelectric film 4. Accordingly, when the thickness T of the piezoelectric film 4 is set to a specific thickness, comparatively large sub-resonance can be generated at a position separated from the main resonance. For example, as illustrated in FIG. 8, when generation of comparatively large sub-resonance in a frequency region where the normalized frequency is about 1.5 is wished, the thickness T of the piezoelectric film 4 may be set to about 0.175λ.

As described above, when the thickness T of the piezoelectric film 4 is set to 0.168λ to 0.288λ, comparatively large sub-resonance can be generated in a high-frequency region where the normalized frequency is higher than or equal to about 1.4. However, this is the result when the duty d of the electrode fingers 512 is 0.6.

When the electrode finger width w is fixed, the pitch p of the electrode fingers 512 varies as the duty d varies. When the pitch p of the electrode fingers 512 varies, the wavelength λ defined as a value double the pitch p varies. As the wavelength λ varies, the resonant frequency fr and the anti-resonant frequency fa vary. Thus, when the duty d varies, the wavelength λ, the resonant frequency fr, and the anti-resonant frequency fa vary. From a different viewpoint, even when the wavelength λ=2p) is fixed, the anti-resonant frequency fa varies as the duty d (electrode finger width w) varies.

Accordingly, when the thickness T of the piezoelectric film 4 is represented by a notation using λ, variations in the pitch p and the wavelength λ due to the variation in the duty d may be considered. Thus, the thickness T of the piezoelectric film 4 is represented by using a corrected wavelength λ_{d} expressed by formula (2). Hereinafter, a method of calculating the corrected wavelength λ_{d} is described.

A plurality of cases in which the pitch p and the duty d are changed into various values are simulated so as to specify the anti-resonant frequency fa. The pitch p of various cases (various duties) is divided by the pitch p of the case where the anti-resonant frequency fa is the same as that in the above-described various cases and the duty d=0.5 to obtain a normalized value that is defined to be a corrected pitch p_{d}.

FIG. 9 illustrates simulation results of the corrected pitches p_{d} in the cases where the duty d is varied in a range from 0.3 to 0.7. The anti-resonant frequency fa is different among a plurality of simulation results plotted for the same duty d. As is clearly seen from FIG. 9, it is understood that the corrected pitches p_{d} of the cases exist on the substantially same curve A.

Referring to FIG. 9, when the duty d is defined as a variable x and the corrected pitch p_{d} is defined as a variable y, an approximate formula of the curve A can be expressed by the following formula (3). At this time, a coefficient of determination R² is 0.9884.

$$y = - 0.6 \; 111 {x}^{2} - 0.1 \; 792 x + 1.2449 . \qquad ( 3 )$$

When assigning the value of the duty d of the electrode fingers 512 to the variable x of the approximate formula (3) of the curve A, the corrected pitch p_{d} (variable y) at this duty d can be obtained. The variation in anti-resonant frequency fa when the duty d is the same are considered in the curve A. When the wavelength λ is normalized with the corrected pitch p_{d} obtained as described above, a corrected wavelength λ_{d} can be calculated.

Specifically, the corrected wavelength λ_{d} can be expressed by the following formula (2). In the corrected wavelength λ_{d} obtained by using formula (2), the variation in the duty d is considered.

$${λ}_{d} = λ / ( - 0.6111 \times {d}^{2} - 0.1792 \times d + 1.2449 ) . \qquad ( 2 )$$

In the high-frequency region where the normalized frequency is higher than or equal to about 1.4, the thickness T of the piezoelectric film 4 with which a comparatively larger sub-resonance can be generated can be expressed by the following formula (1) by using the corrected wavelength λ_{d} obtained by formula (2) described above.

$$0.154 {λ}_{d} \leq T \leq 0 \text{.264} {λ}_{d} . \qquad ( 1 )$$

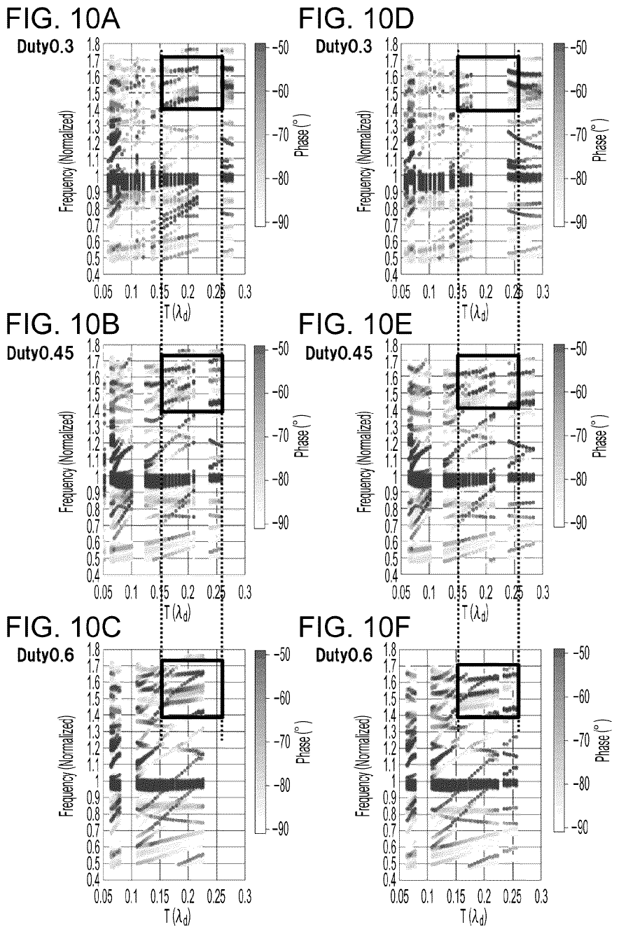

FIGS. 10A to 10F illustrate simulation results of the frequency characteristics of the acoustic wave filter 3 when the duty d is varied. FIGS. 10A to 10C illustrate cases where the anti-resonant frequency fa of the acoustic wave resonator 31 is the same. FIG. 10A is the simulation result of the frequency characteristics of the acoustic wave filter 3 with the duty d set to 0.3, FIG. 10B is the simulation result of the frequency characteristics of the acoustic wave filter 3 with the duty d set to 0.45, and FIG. 10C is the simulation result of the frequency characteristics of the acoustic wave filter 3 with the duty d set to 0.6. FIGS. 10D to 10F illustrate the simulation results of the frequency characteristics of the acoustic wave filter 3 when the anti-resonant frequency fa of the acoustic wave resonator 31 is different from that of the cases of in FIGS. 10A to 10C.

In FIGS. 10A to 10F, the vertical axis represents the normalized frequency, and the horizontal axis represents the thickness T of the piezoelectric film 4. The thickness T of the piezoelectric film 4 is represented by using the corrected wavelength λ_{d}.

As is clearly seen from FIGS. 10A to 10F, when the thickness T of the piezoelectric film 4 of the acoustic wave resonator 31 is in a range expressed by formula (1), comparatively large sub-resonance can be generated in the high-frequency region where the normalized frequency is higher than or equal to about 1.4.

For example, when the acoustic wave filter 3 is the BEF, setting a passband of the LC filter 2 on the low-frequency side relative to the obtained sub-resonance improves the attenuation characteristics of the LC filter 2 outside the passband. Thus, the filter device 1 having a steep passband can be provided. Accordingly, the sub-resonance of the acoustic wave resonator 31 can be utilized as the attenuation pole. This attenuation pole by using the sub-resonance of the acoustic wave resonator 31 is defined as a second attenuation pole.

Furthermore, when the first attenuation pole and the second attenuation pole are positioned such that the passband of the LC filter 2 is interposed between the first attenuation pole and the second attenuation pole, the attenuation characteristics are improved on both the low-frequency side and the high-frequency side of the passband. Thus, the filter device 1 having a steep passband can be provided.

In addition, it has been found that, when the thickness T of the piezoelectric film 4 is set in a range expressed by formula (1), in a range from the anti-resonant frequency fa to the sub-resonance of the acoustic wave resonator 31, a low spurious region including little spurious of a larger phase than that of the sub-resonance can be obtained. According to the embodiment of the present disclosure, the low spurious region refers to a region not including spurious larger than the phase of the sub-resonance therein.

For example, referring to FIG. 10A, when the thickness T of the piezoelectric film 4 is set to 0.2λ_{d}, comparatively larger sub-resonance is generated in a frequency region where the normalized frequency is 1.45. However, spurious larger than the phase of this sub-resonance is not observed in a range of the normalized frequency from 1 to 1.45.

According to an embodiment of the present disclosure, superposition of the passband of the LC filter 2 on the low spurious region of the acoustic wave resonator 31 can reduce degradation of frequency transmission characteristics of the LC filter 2 due to spurious characteristics of the acoustic wave resonator 31.

As described above, with a configuration according to the embodiment of the present disclosure, a filter device having a wide passband and good frequency characteristics can be provided. According to an embodiment of the present disclosure, addition of a matching inductor or a matching capacitor to the acoustic wave filter 3 to adjust the frequency of the sub-resonance is not required. Accordingly, the size of the filter device can be reduced.

As an embodiment of the present disclosure, the acoustic wave mode of the main resonance and the sub-resonance is analyzed with the thickness T of the piezoelectric film 4 of the acoustic wave resonator 31 set to 0.184λ and the duty d of the electrode fingers 512 set to 0.6. From the result of this, it has been found that the main resonance of the acoustic wave filter 3 according to an embodiment of the present disclosure may include resonance due to a Lamb wave Al mode. Furthermore, the sub-resonance of the acoustic wave resonator 31 according to an embodiment of the present disclosure may include various acoustic wave modes. This may include resonance due to a Lamb wave Si mode.

Although the acoustic wave filter 3 is a ladder filter including the at least one series resonator 311 and the at least one parallel resonator 312 according to an embodiment of the present disclosure, the configuration of the acoustic wave filter 3 is not limited to this. For example, the acoustic wave filter 3 may include a single acoustic wave resonator 31. With such a configuration, both the main resonance forming the first attenuation pole and the sub-resonance forming the second attenuation pole are ascribable to the single acoustic wave resonator 31.

In another example of the present disclosure, the acoustic wave filter 3 may include a plurality of resonators, and out of the plurality of resonators, a single resonator is the acoustic wave resonator 31. With such a configuration, the sub-resonance forming the second attenuation pole is ascribable to the single acoustic wave resonator 31.

Although the acoustic wave filter 3 does not include an inductor or a capacitor according to an embodiment of the present disclosure, the configuration of the acoustic wave filter 3 is not limited to this. For example, the acoustic wave filter 3 may include the capacitor. With such a configuration, the frequency characteristics of the acoustic wave filter 3 can be varied due to an additional capacity. The acoustic wave filter 3 is not limited to such a configuration. For example, the acoustic wave filter 3 may include the inductor or both the inductor and the capacitor.

The anti-resonant frequency fa of the acoustic wave resonator 31 may be appropriately set. For example, the anti-resonant frequency fa of the acoustic wave resonator 31 may be higher than or equal to 3300 MHz.

Although the filter device 1 includes the LC filter 2 according to an embodiment of the present disclosure, the configuration of the filter device 1 is not limited to this. For example, as illustrated by two-dot chain line in FIG. 12 to be described later, the filter device 1 (a transmission filter 106 in FIG. 12) may include the acoustic wave filter 3 and a second acoustic wave filter 302 different from the acoustic wave filter 3. The second acoustic wave filter 302 may be, for example, one selected from the group consisting of the BPF, the LPF, and the HPF. The second acoustic wave filter 302 may be provided instead of the LC filter 2 or in addition to the LC filter 2. The position of the second acoustic wave filter 302 (whether the second acoustic wave filter 302 is provided in front of or at the rear of the acoustic wave filter 3) is arbitrarily determined. Similarly, also in this case, the at least one resonator out of the resonators included in the acoustic wave filter 3 can be the acoustic wave resonator 31.

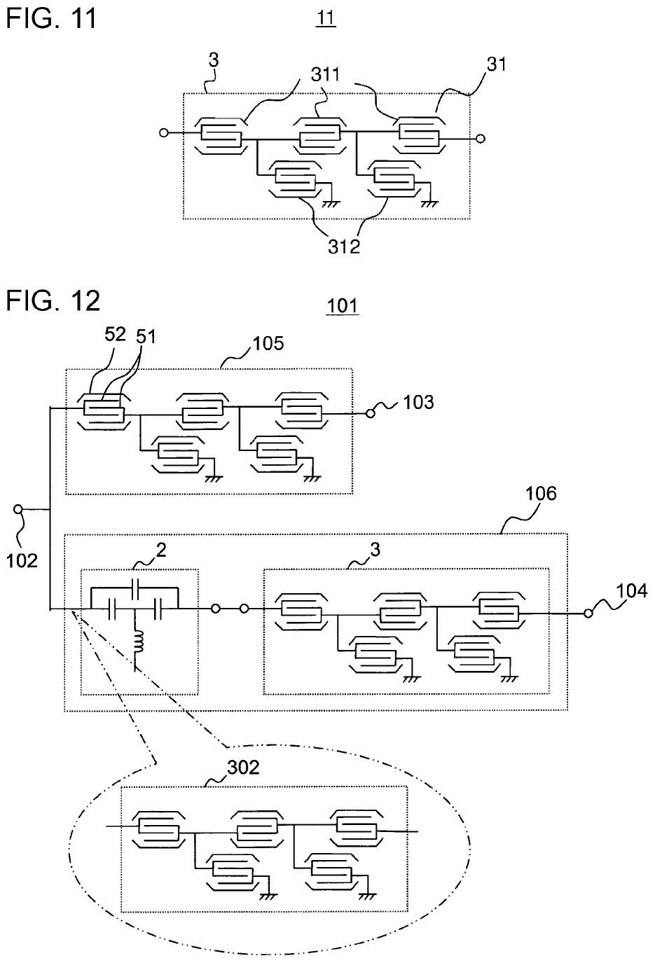

Although the acoustic wave filter 3 is the BEF according to an embodiment of the present disclosure, the configuration of the acoustic wave filter 3 is not limited to this. For example, as illustrated in FIG. 11, the acoustic wave filter 3 itself may be the BPF. This example is referred to as a filter device 11.

The filter device 11 does not necessarily include a BPF other than the acoustic wave filter 3. Similarly to the filter device 1, in the filter device 11, at least one resonator out of the resonators included in the acoustic wave filter 3 can be the acoustic wave resonator 31.

In the filter device 11, the resonant frequency fr in the parallel resonator 312 positioned on the lowermost frequency side of the passband of the acoustic wave filter 3 is the frequency of the first attenuation pole.

### Example of Utilization of Filter Device 1: Splitter

FIG. 12 is a circuit diagram schematically illustrating a configuration of a splitter 101 as an example of utilization of the filter device 1. As can be understood from signs indicated at the upper left of the page of FIG. 12, the comb-shaped electrodes 51 are schematically illustrated in FIG. 12 by using a fork shape including two prongs, and the reflectors 52 are represented by a line including bends at both ends.

The splitter 101 includes, for example, the transmission filter 105 and a reception filter 106. The transmission filter 105 is configured to filter a transmission signal from a transmission terminal 103 and output the filtered signal to an antenna terminal 102. The reception filter 106 is configured to filter a reception signal from the antenna terminal 102 and output the filtered signal to a reception terminal 104.

For example, the filter device 1 according to an embodiment of the present disclosure may be used as at least one of the transmission filter 105 or the reception filter 106. The filter device 1 may be used as both the transmission filter 105 and the reception filter 106.

As an example, in the splitter 101 illustrated in FIG. 12, the filter device 1 is used as the reception filter 106. The transmission filter 105 includes, for example, a ladder filter including a plurality of resonators connected in a ladder shape. That is, the transmission filter 105 includes a plurality of resonators connected in series (or a single resonator) between the transmission terminal 103 and the antenna terminal 102 and a plurality of resonators (or a single resonator) connecting the series line (a series arm) and the reference potential (a parallel arm).

FIG. 12 illustrates merely an example of the configuration of the splitter 101. The configuration of the splitter 101 is not limited to the configuration illustrated in FIG. 12. For example, such a configuration in which the transmission filter 105 includes a multi-mode filter is possible. Although the transmission filter 105 is an acoustic wave filter in FIG. 12, the configuration of the transmission filter 105 is not limited to this. For example, the transmission filter 105 may be an LC filter including at least one inductor and at least one capacitor.

Although the case where the splitter 101 includes the transmission filter 105 and the reception filter 106 has been described, the configuration of the splitter 101 is not limited to this. For example, the splitter 101 may be a diplexer or a multiplexer including three or more filters.

As a filter included in the splitter 101, the filter device 11 may be used instead of the filter device 1.

### Example of Utilization of Filter Device 1: Communication Device

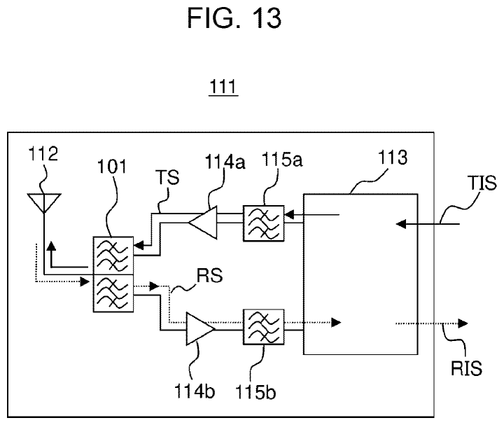

FIG. 13 is a block diagram illustrating a main part of a communication device 111 as an example of utilization of the filter device 1 (splitter 101). The communication device 111 is configured to perform wireless communication utilizing a radio wave and includes the splitter 101.

In the communication device 111, a radio frequency-integrated circuit (RF—IC) 113 modulates a transmission information signal TIS including information to be transmitted and increases the frequency of the transmission information signal TIS (converts the carrier wave frequency into a radio frequency signal). Thus, the transmission information signal TIS is changed into a transmission signal TS. An unnecessary component other than the pass band for transmission is removed from the transmission signal TS by a band pass filter 115a and the transmission signal TS is amplified by an amplifier 114a. This transmission signal TS is input to the splitter 101 (transmission terminal 103). The splitter 101 (transmission filter 105) removes an unnecessary component other than the pass band for transmission from the input transmission signal TS and outputs, from the antenna terminal 102 to an antenna 112, the transmission signal TS after the removal. The antenna 112 is configured to convert the input electric signal (transmission signal TS) into a wireless signal (radio wave) and transmit the wireless signal.

Also in the communication device 111, a wireless signal (radio wave) received by the antenna 112 is converted into an electric signal (reception signal RS) by the antenna 112 and input to the splitter 101 (antenna terminal 102). The splitter 101 (reception filter 106) is configured to remove an unnecessary component other than the pass band for reception from the input reception signal RS and output, from the reception terminal 104 to an amplifier 114b, the reception signal RS. The output reception signal RS is amplified by the amplifier 114b, and an unnecessary component other than the pass band for reception is removed from the reception signal RS by a band pass filter 115b. The RF—IC 113 reduces the frequency of the reception signal RS and demodulates the reception signal RS. Thus, the reception signal RS is changed into a reception information signal RIS.

The transmission information signal TIS and the reception information signal RIS may be low-frequency signals (baseband signals) including appropriate information and are, for example, analog sound signals or digitized sound signals. The pass band of the wireless signal may be appropriately set. According to the present embodiment, a pass band of a comparatively high frequency (for example, higher than or equal to 5 GHz) is possible. The modulation method is one selected from the group consisting of phase modulation, amplitude modulation, and frequency modulation, or a combination of two or more selected from the group consisting of phase modulation, amplitude modulation, and frequency modulation. Although the circuit method is exemplified by a direct conversion method in FIG. 13, the circuit method may be an appropriate method other than the direct conversion method. For example, the circuit method may be a double superheterodyne method. FIG. 13 schematically illustrates only the main part. A low-pass filter, an isolator, or the like may be added at an appropriate position, or the positions of the amplifiers or the like may be changed.

It has already been described that the conditions of the piezoelectric film 4 other than the thickness T may be various conditions. Specific examples of a subset of the conditions are listed below. When the following specific examples are satisfied, for example, the effects of the embodiment that have been described above improve. The following specific examples are based on the results of simulations having been performed and an empirical rule of the applicant.
Euler angles of LN: (including angles equivalent to angles described below)
   ϕ: larger than or equal to −30° and smaller than or equal to 30°, 0°±10°, or 0°+1°.
   θ: larger than or equal to 0° and smaller than or equal to 60°, 15°±10°, or 15°±1°.
   ψ: larger than or equal to −30° and smaller than or equal to 30°, 0°±10°, or 0°±1°.

For example, 0°±10° indicates larger than or equal to −10° and smaller than or equal to 100.
Material of electrode: greater than or equal to 70%, greater than or equal to 90%, or greater than or equal to 95% of thickness (and/or volume) is Al or Al—Cu alloy. Cu is smaller than or equal to 10 wt %, smaller than or equal to 5 wt %, or smaller than or equal to 1 wt %.
Thickness of electrode: greater than or equal to 50 nm and smaller than or equal to 400 nm, greater than or equal to 100 nm and smaller than or equal to 200 nm, or greater than or equal to 100 nm and smaller than or equal to 150 nm.
Thickness of piezoelectric film: greater than or equal to 300 nm and smaller than or equal to 600 nm, greater than or equal to 400 nm and smaller than or equal to 500 nm, or greater than or equal to 450 nm and smaller than or equal to 500 nm.
Pitch of electrode finger: greater than or equal to 0.8 μm and smaller than or equal to 3.0 μm, greater than or equal to 0.8 μm and smaller than or equal to 2.0 μm, or greater than or equal to 0.8 μm and smaller than or equal to 1.5 μm.
Duty: greater than or equal to 0.2 and smaller than or equal to 0.7.

### REFERENCE SIGNS

1, 11 filter device
2 LC filter
21 inductor
22 capacitor
23 multilayer substrate
231 dielectric layer
232 conductor layer
3 acoustic wave filter
31 acoustic wave resonator
311 series resonator
312 parallel resonator
302 second acoustic wave filter
4 piezoelectric film
5 IDT electrode
51 comb-shaped electrode
511 busbar
512 electrode finger
513 dummy electrode finger
52 reflector
6 supporting substrate
7 multilayer film layer
71 low acoustic impedance layer
72 high acoustic impedance layer
8 cavity
101 splitter
102 antenna terminal
103 transmission terminal
104 reception terminal
105 transmission filter
106 reception filter
111 communication device
112 antenna
113 RF—IC
114 amplifier

1. A filter device comprising:
at least one acoustic wave resonator,
wherein the acoustic wave resonator includes
a piezoelectric film having a piezoelectric property, and
an interdigital transducer electrode positioned on an upper surface of the piezoelectric film, the interdigital transducer electrode including a plurality of electrode fingers, and
wherein, when a value double a pitch of the plurality of electrode fingers is defined as λ and a duty of the plurality of electrode fingers is defined as d,
a thickness T of the piezoelectric film satisfies formula (1) below, and
wherein the filter device has a second attenuation pole by using sub-resonance of the acoustic wave resonator on a high-frequency side of a passband of the filter device.
$$0.154 {λ}_{d} \leq T \leq 0 \text{.264} {λ}_{d} , \qquad ( 1 )$$
where λ_{d} satisfies formula (2) below:
$${λ}_{d} = λ / ( - 0.6111 \times {d}^{2} - 0.1792 \times d + 1.2449 ) \qquad ( 2 )$$

2. The filter device according to claim 1, further comprising:
a first acoustic wave filter including the acoustic wave resonator,
wherein the filter device has a first attenuation pole by using main resonance of the first acoustic wave filter on a low-frequency side of the passband of the filter device.

3. The filter device according to claim 1, further comprising:
an LC filter,
wherein the LC filter is one selected from the group consisting of a band-pass filter, a high-pass filter, and a low-pass filter.

4. The filter device according to claim 1,
wherein the acoustic wave resonator is included in a band elimination filter.

5. The filter device according to claim 1, further comprising:
a second acoustic wave filter,
wherein the second acoustic wave filter is one selected from the group consisting of a band-pass filter, a high-pass filter, and a low-pass filter.

6. The filter device according to claim 1,
wherein the acoustic wave resonator is included in a band-pass filter.

7. The filter device according to claim 1,
wherein, when an anti-resonant frequency of the acoustic wave resonator is fa and a frequency of sub-resonance of the acoustic wave resonator is fb,
the acoustic wave resonator does not include, in a range from fa to fb, resonance having a larger phase than a phase of the sub-resonance.

8. The filter device according to claim 1,
wherein, when the anti-resonant frequency of the acoustic wave resonator is fa and the frequency of the sub-resonance of the acoustic wave resonator is fb,
fb/fa is greater than or equal to 1.4.

9. The filter device according to claim 1,
wherein the piezoelectric film is LiNbO₃.

10. The filter device according to claim 1,
wherein the main resonance includes resonance due to a Lamb wave A1 mode.

11. The filter device according to claim 1,
wherein the sub-resonance includes resonance due to a Lamb wave S1 mode.

12. The filter device according to claim 2,
wherein the first acoustic wave filter does not include an inductor.

13. The filter device according to claim 2,
wherein the first acoustic wave filter does not include a capacitor.

14. The filter device according to claim 2,
wherein, when the at least one acoustic wave resonator includes a plurality of acoustic wave resonators, the sub-resonance is ascribable to one of the plurality of acoustic wave resonators.

15. The filter device according to claim 3, further comprising:
a multilayer substrate including a dielectric layer and a conductor layer,
wherein the LC filter includes the multilayer substrate.

16. A splitter comprising:
an antenna terminal;
a transmission filter configured to filter a signal to be output to the antenna terminal; and
a reception filter configured to filter a signal to be input from the antenna terminal,
wherein at least one of the transmission filter or the reception filter includes the filter device according to claim 1.

17. A communication device comprising:
an antenna;
the splitter according to claim 16, the antenna terminal of the splitter being connected to the antenna; and
an integrated circuit connected to the transmission filter and the reception filter.
